(19) United States
(12) Patent Application Publication
(10) Pub. No.: US 2007/0077766 A1
(43) Pub. Date: Apr. 5, 2007

(54) Method for fabricating image sensor

(75) Inventors: Sang Il Hwang, Wonju-si (KR); Cheon Man Shim, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/542,078

(22) Filed: Oct. 2, 2006

(30) Foreign Application Priority Data
Sep. 30, 2005 (KR) 10-2005-0092216

(51) Int. Cl. H01L 21/461; H01L 21/302; H01L 21/4763

(52) U.S. Cl. 438/706; 438/618

(57) ABSTRACT

The present invention relates to a method of fabricating an image sensor wherein it can enhance adhesive strength between an USG layer and a SiN layer. The method of fabricating the image sensor according to the present invention includes patterning a metal pad on a circuit region of a substrate; forming an Undoped Silicate Glass (USG) film on the substrate to cover the metal pad; plasma treating a surface of the USG film; forming a silicon nitride (SiN) film on the USG film; selectively etching the SiN layer and the USG layer to expose the metal pad; and forming a color filter array and a microlens on the SiN film in a photosensitive element region of the substrate. In accordance with the method, an adhesive strength between the USG film and the SiN film can be enhanced. It is therefore possible to reduce or prevent the peeling phenomenon in which the SiN film peels off from the USG film.

This application claims the benefit of Korean Application No. 10-2005-0092216, filed on Sep. 30, 2005, which is incorporated by reference herein in its entirety.

### BACKGROUND OF THE INVENTION

1. Field of the Invention

The present invention relates to an image sensor, and more particularly, to a method for fabricating an image sensor which can enhance an adhesive strength between an undoped silicate glass (USG) layer and a silicon nitride (SiN) layer.

2. Background of the Related Art

In general, an image sensor is a semiconductor device that converts an optical image into an electrical signal. Among image sensors, a Charge Coupled Device (CCD) is an element in which respective Metal Oxide Silicon (MOS) capacitors are located closely, and charge carriers are stored in the capacitors and moved. Furthermore, a Complementary MOS (CMOS) image sensor is an element that adopts the switching method of sequentially detecting outputs by employing MOS transistors in unit pixels using CMOS technology, in which a control circuit and a signal processing circuit are peripheral circuits.

In fabricating the image sensor, several attempts have been made to improve the photosensitivity of the image sensor. One of the attempts is a focusing technique. For example, the CMOS image sensor includes a photosensitive element part for sensing light, and a CMOS logic circuit part for processing the sensed light into an electrical signal in order to produce data. Furthermore, an attempt has been made to increase a ratio of the area of the photosensitive element part that occupies the whole area of the image sensor (generally referred to as a “fill factor” or “filter factor”) in order to increase the photosensitivity. However, since the logic circuit part cannot be removed fundamentally, such an attempt (or ratio) has a limitation.

FIGS. 1a to 1f are cross-sectional views illustrating a method for fabricating a conventional image sensor.

Referring to FIG. 1a, an insulating layer 2 is formed on a semiconductor substrate 1 in which field insulating layers (not shown) for electrical insulation between unit pixels of the image sensor, one or more photosensitive elements (not shown), and logic circuits (not shown) between the field insulating layers are formed.

A metal pad 4 made of aluminum (Al) or copper (Cu) is formed over the insulating layer 2. Lower and upper barrier layers 3 and 5 are formed below and on the metal pad 4, respectively. The lower and upper barrier layers 3 and 5 are formed by depositing a material, such as titanium (Ti) or titanium nitride (TiN), and they are used as barriers for increasing the conductivity of a contact part, improving adhesion of the metal pad to surrounding (or underlying) insulator layers, and/or preventing diffusion of atoms between the metal pad and the adjacent insulator layer(s).

The upper barrier layer 5, the metal pad 4 and the lower barrier layer 3 are sequentially stripped by an etch process using a photoresist PR formed in a predetermined region on the resulting structure (a metal pad region in which logic circuits will be formed) as a mask.

Referring to FIG. 1b, a USG (Undoped Silicate Glass) layer 6b and a silicon nitride (SiN) layer 6a are sequentially deposited on the insulating layer 2 of the substrate 1 in order to protect the elements from external moisture and scratches. Meanwhile, in FIG. 1b, reference letter A indicates the photosensitive element region and reference letter B indicates the logic circuit region.

Referring to FIG. 1c, a photoresist PR is coated on the SiN layer 6a in the region other than the pad open region, thus opening the metal pad parts 3, 4 and 5.

Referring to FIG. 1d, the SiN layer 6a, the USG layer 6b and the upper barrier layer 5 in the pad open region are stripped by a TV (Terminal Via) etch process using the photoresist PR coated on the SiN layer 6a as a mask. In the TV etch process, CHF₃, CH₄, and N₂ gases are used, and when the upper barrier layer 5 comprises or consists essentially of TiN, the etch process is performed at an etch ratio of USG:TiN=10:1. The USG layer 6a and the SiN layer 6b, and the upper barrier layer 5 are etched by the TV etch process, thus exposing the metal pad 4. The exposed portion C of the metal pad is used as a region at which wire bonding will be performed during the subsequent process of packaging the image sensor.

Referring to FIG. 1e, a photoresist is coated on the SiN layer 6a over the photosensitive element region A in order to minimize adverse effects (e.g., get rid) of the topology and enhance the adhesion. The photoresist is patterned by exposure and development processes, resulting in a first planarization layer 7.

Referring to FIG. 1f, dyed photoresists are coated on the first planarization layer 7 in the photosensitive element region A. The photoresists are patterned by exposure and development processes, thus forming a color filter array 8 generally including red, green, and blue color filters. A second planarization layer 9 is formed on the first planarization layer 7 having the color filter arrays 8 thereon in such a way to surround the color filter arrays 8.

Thereafter, a photoresist is coated on the second planarization layer 9 in the photosensitive element region A, and is then patterned by exposure and development processes, so that the photoresist pattern remains at a location above and corresponding to the color filter array 8. An annealing process is then performed in order to flow or reflow the photoresist pattern, thus forming a hemispherical microlens 10 on the second planarization layer 9 for focusing light on a photosensitive element in the substrate below. The fabrication process of the image sensor is thereby completed.

In the conventional fabrication process of the image sensor, a peeling phenomenon in which the SiN layer 6a peels off in a substantially circular fashion during the annealing process, such as during TV sintering, due to poor adhesion with the USG layer 6b, as shown in FIG. 2. In other words, the peeling phenomenon of the SiN layer 6a occurs when the SiN layer 6a separates from the USG layer 6b due to stress which is generated when the substrate is cooled after a TV sintering process. The peeling phenomenon is caused by a difference in rates of thermal expansion and/or contraction between oxide and metal. Accordingly, the peeling phenomenon generally occurs in the vicinity of the metal pad unit C.

As a result, in the conventional fabrication process of the image sensor, fragments of the SiN layer 6a, which peel off due to the peeling phenomenon of the SiN layer 6b, drop on the pattern of the device, thereby causing failures in the image sensor.

### SUMMARY OF THE INVENTION

Accordingly, the present invention has been made in view of the above-mentioned problems occurring in the related art, and it is an object of the present invention to provide a method for fabricating an image sensor, which can improve an adhesive strength between an USG layer and a SiN layer.

To achieve the above object, according to an aspect of the present invention, there is provided a method of fabricating an image sensor, including the steps of: patterning a metal pad on a circuit region of a substrate; forming an Undoped Silicate Glass (USG) film on the substrate so as to cover the metal pad; treating a surface of the USG film with a plasma comprising oxygen (O₂); forming a silicon nitride (SiN) film on the plasma treated USG film; selectively etching the SiN layer and the USG layer to expose the metal pad; and forming a color filter array and a microlens on the SiN film over a photosensitive element region of the substrate.

The step of plasma treating the surface of the USG film may include employing a chemical dry etching process using a remote plasma apparatus.

In the chemical dry etching process, a flow rate of oxygen (O₂) gas may be within a range of from 400 to 500 sccm, a pressure may be within a range of from 40 to 50 Pa, and/or a processing time may be within a range of from 50 to 100 sec.

The step of forming and/or patterning the metal pad on the circuit region of the substrate may include one or more of the steps of forming an insulating film on the substrate, sequentially forming a lower barrier film comprising a metal material, the metal pad and an upper barrier film on the insulating film, and selectively stripping a portion of the lower barrier film, the metal pad and the upper barrier film.

The step of forming the color filter array and/or the microlens may include one or more of the steps of forming a first planarization layer on the SiN film over the photosensitive element region of the substrate, forming the color filter array on the first planarization layer, forming a second planarization layer to cover the color filter array, and forming the microlens on the second planarization layer.

The present invention will now be described in detail in connection with specific embodiments with reference to the accompanying drawings.

### BRIEF DESCRIPTION OF DRAWINGS

FIGS. 1a to 1f are cross-sectional views illustrating a method for fabricating a conventional image sensor;

FIG. 2 is a photograph showing the peeling phenomenon in which the SiN layer shown in FIG. 1f is peeled off; and

FIGS. 3a to 3h are cross-sectional views illustrating a method for fabricating an image sensor according to an embodiment of the present invention.

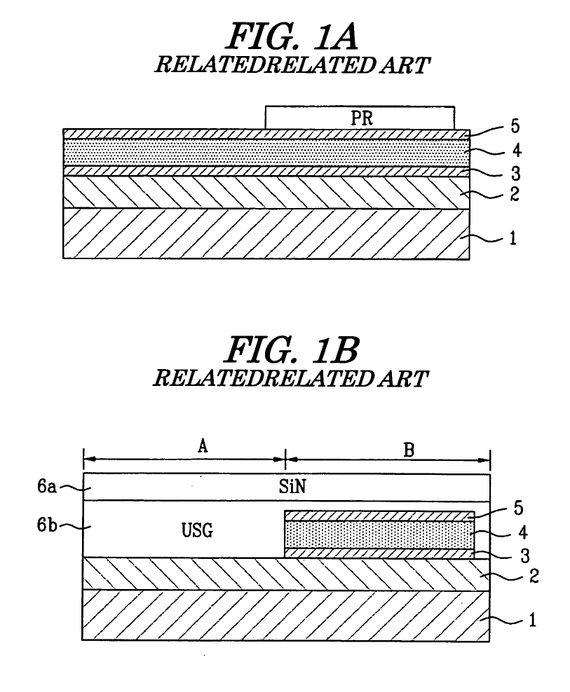

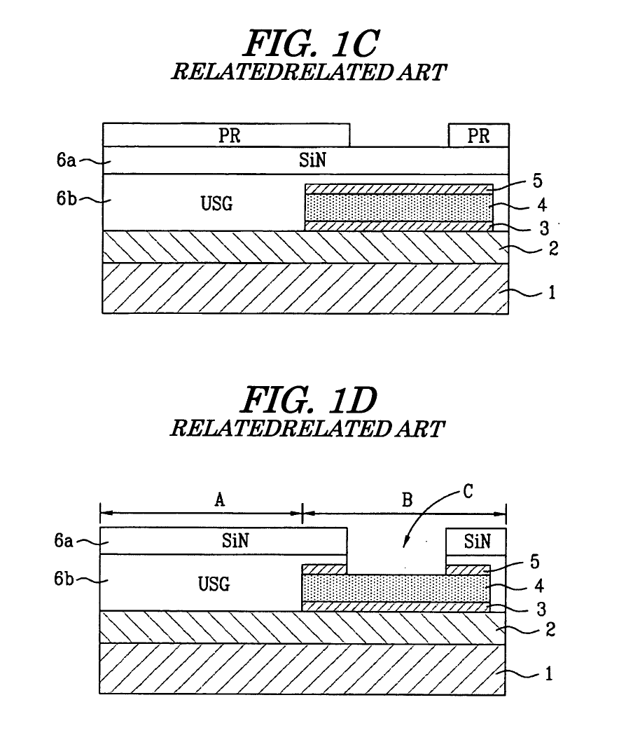

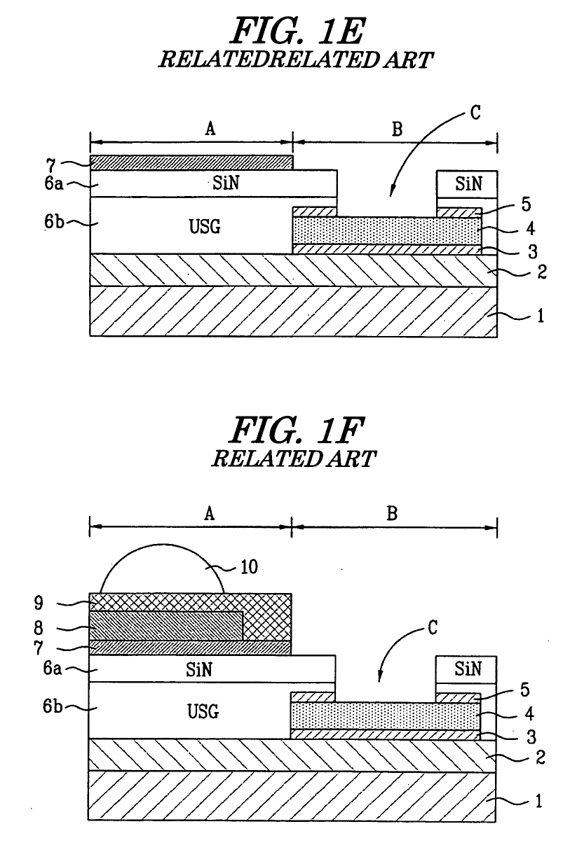

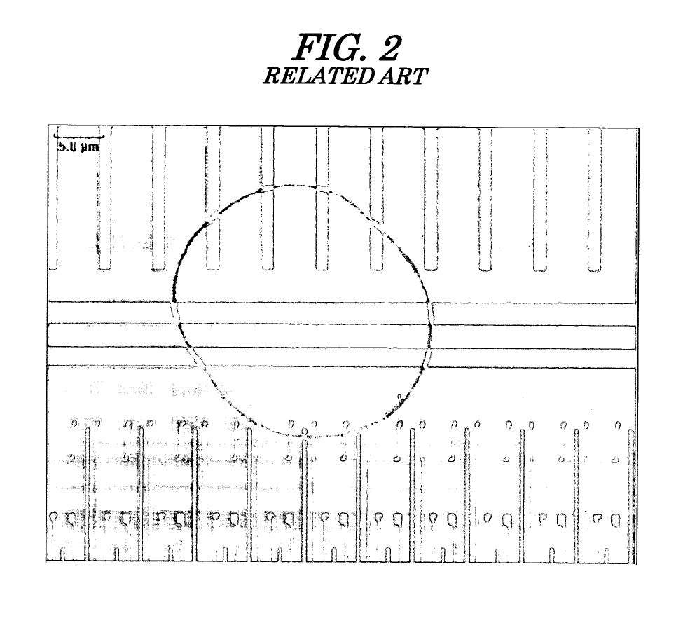

### DETAILED DESCRIPTION OF THE INVENTION

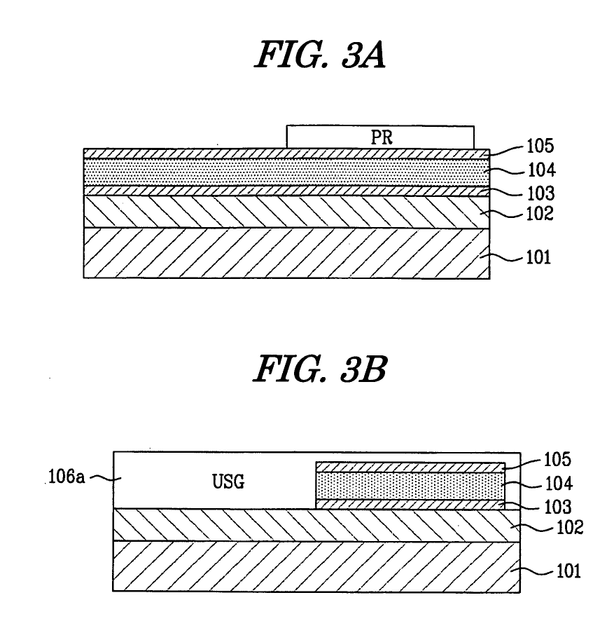

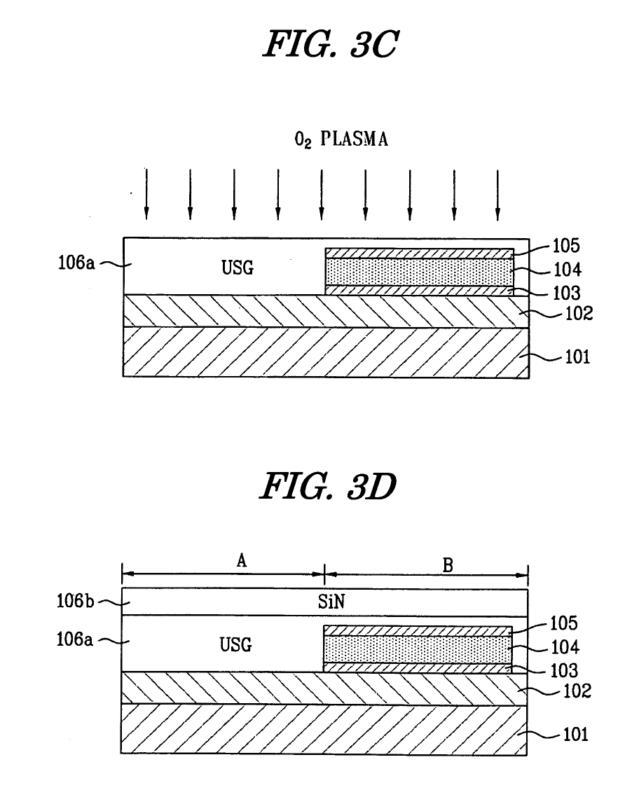

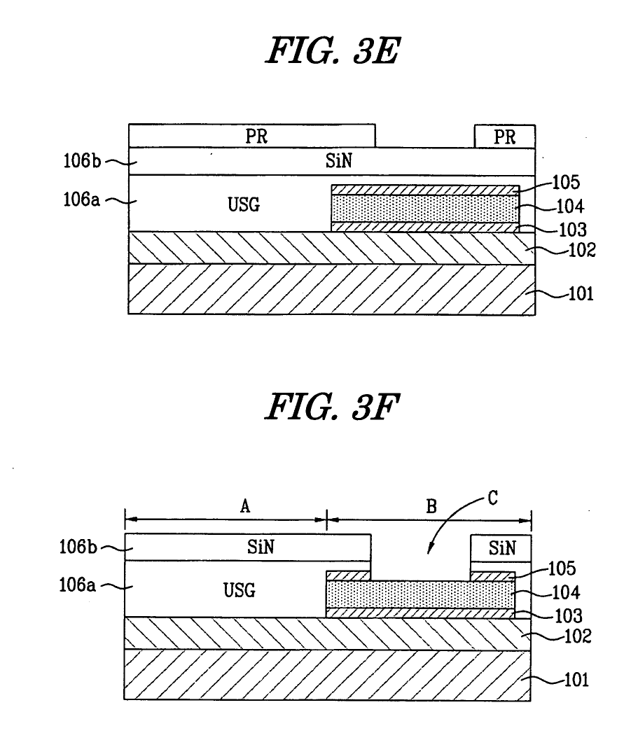

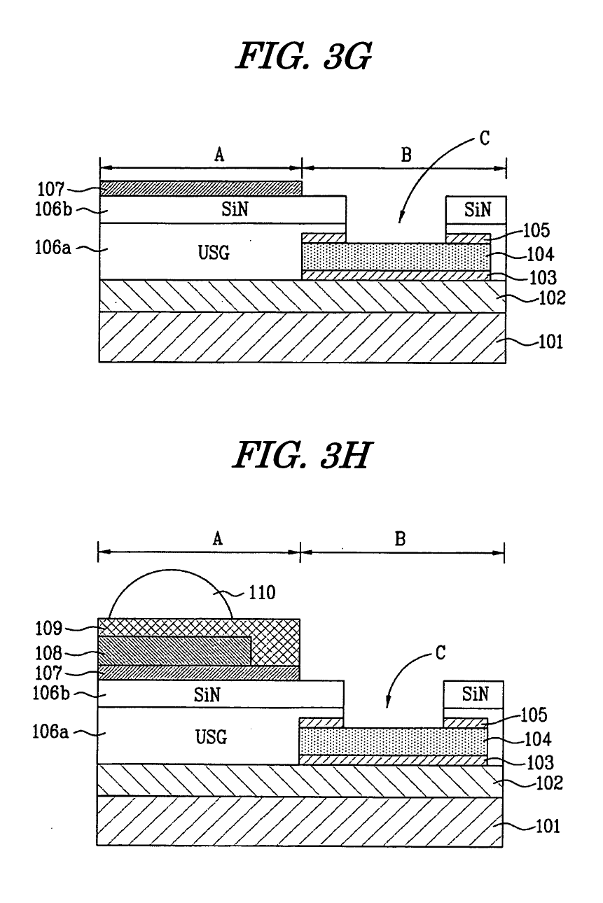

FIGS. 3a to 3h are cross-sectional views illustrating a method of fabricating an image sensor according to an embodiment of the present invention.

Referring to FIG. 3a, an insulating layer 102 is formed on a semiconductor substrate 101 in which field insulating layers (not shown) for electrical insulation between unit pixels of the image sensor, and one or more photosensitive elements (not shown) and logic circuits (not shown) between the field insulating layers are formed.

A metal pad 104 comprising aluminum (Al), and aluminum alloy (e.g., Al with from 0.5 to 4.0 wt. % Cu and up to 1.0 wt. % Si) or copper (Cu) is formed over the insulating layer 102. Lower and upper barrier layers 103 and 105 are formed below and on the metal pad 104, respectively. The lower and upper barrier layers 103 and 105 are formed by depositing (and thus may comprise) a material, such as titanium (Ti) and/or titanium nitride (TiN), and they may increase the conductivity of a contact part, improve adhesion of the metal pad to surrounding (or underlying) insulator layers, and/or prevent diffusion of atoms between the metal pad and the adjacent insulator layer(s). Alternatively (and particularly when the metal pad 104 comprises copper), the lower and upper barrier layers 103 and 105 may comprise tantalum (Ta) and/or tantalum nitride (TaN).

The upper barrier layer 105, the metal pad 104 and the lower barrier layer 103 are sequentially stripped (e.g., selectively etched) by an etch process using a photoresist PR formed in a predetermined region (especially, a metal pad region, optionally in which a logic circuit region will be formed) on the resulting structure as a mask.

Referring to FIG. 3b, a USG layer 106a is deposited on the insulating layer 102 of the substrate 101 in order to protect the elements from external moisture, oxidizing agents (such as air or molecular oxygen), and scratches or other physical damage. Optionally, the deposited USG layer 106a may be planarized by chemical-mechanical polishing. Accordingly, the metal pad units 103, 104 and 105 formed on the insulating layer 102 are covered with the USG layer 106a.

Referring to FIG. 3c, an oxygen (O₂) plasma process is performed on a surface of the USG layer 106a using a CDE (Chemical Dry Etching) apparatus (e.g., a remote plasma apparatus) in order to prevent plasma damage to the image sensor. An oxygen (O₂) plasma process, or an oxygen plasma treatment, generally refers to a process that exposes an object such as a semiconductor wafer (generally with one or more layers of material thereon) to a plasma comprising an oxygen source, such as dioxygen (O₂), ozone (O₃), carbon monoxide (CO), carbon dioxide (CO₂), nitrogen oxides (NO, NO₂), etc. Such a plasma may contain reactive species, such as singlet oxygen, oxygen atoms, dioxygen and/or ozone radicals and/or ions, etc., and/or be formed from one or more additional component gases, such as the noble gases (He, Ne, Ar, etc.). At the time of the oxygen (O₂) plasma process, the flow rate of oxygen (O₂) is preferably from about 400 to about 500 sccm, and microwave power used to generate remote plasma is preferably from about 600 to about 700 W. Furthermore, the pressure is preferably from about 40 to about 50 Pa, and the processing time is preferably from about 50 to about 100 sec.

Referring to FIG. 3d, a SiN layer 106b is deposited on the USG layer 106a on which oxygen (O₂) plasma treatment has been performed. Therefore, the SiN layer 106b more strongly adheres to the plasma treated USG layer 106a. Meanwhile, in FIG. 3d, reference letter A indicates the photosensitive element region and reference letter B indicates the logic circuit and/or metal pad region.

Referring to FIG. 3e, a photoresist PR is coated on the SiN layer 106b in regions other than the pad open region in order to open the metal pad layers 103, 104 and 105.

Referring to FIG. 3f, the SiN layer 106b, the USG layer 106a and the upper barrier layer 105 in the pad open region C are stripped or removed by etching, using the photoresist PR coated on the SiN layer 106b as a mask. In the TV etch process, an etching plasma may be formed from a fluorocarbon and/or hydrofluorocarbon (e.g., CF₄, CHF₃, etc.), an optional hydrocarbon (e.g., CH₄) and an inert or carrier gas (e.g., He, Ne, Ar, N₂, etc.), and the etch process is performed at an etch ratio of USG:barrier layer 105 of at least 3:1, 5:1, 7:1 or more. For example, when barrier layer 105 is TiN, the etch ratio may be =10:1. The USG layer 106a, the SiN layer 106b, and the upper barrier layer 105 are etched by the TV etch process, thus exposing the metal pad 104. The exposed metal pad unit C is a region at which wire bonding will be performed during a subsequent process of packaging the image sensor.

Referring to FIG. 3g, a photoresist is coated on the SiN layer 106b in the photosensitive element region A (i.e., over a photosensitive element in the substrate in region A) in order to overcome the step (or reduce the adverse effects) of the topology (e.g., in the pad region C) and enhance adhesion of subsequently formed layers. The photoresist is patterned by exposure and development processes, thus forming a first planarization layer 107.

Referring to FIG. 3h, a dyed photoresist is coated on the first planarization layer 107 in the photosensitive element region A. The photoresist is patterned by exposure and development processes, thus forming a first color filter. The process is generally repeated at least two (2) more times to form second and third color filters, thus forming (in one embodiment) a red, green and blue color filter array 108. Alternatively, the color filter array may comprise or consist of yellow, cyan and magenta color filters. A second planarization layer 109 is formed on the first planarization layer 107 having the color filter array 108 thereon in such a way as to surround the color filter array 108.

Thereafter, a photoresist is coated on the second planarization layer 109 in the photosensitive element region A and then patterned by exposure and development processes, so that the photoresist pattern remains at a location above and corresponding to the color filter array 108. An annealing process is then performed in order to flow the photoresist pattern, thus forming a hemispherical microlens 110 on the second planarization layer 109 for focusing light onto a corresponding photosensitive element in the substrate below the microlens 110 and a corresponding color filter. The fabrication process of the image sensor is thereby completed.

In the fabrication method of the image sensor according to an embodiment of the present invention, an oxygen (O₂) plasma treatment process is performed on the surface of the USG layer 106a in order to enhance adhesive strength between the USG layer 106a and the SiN layer 106b. It is therefore possible to reduce or prevent the peeling phenomenon by which the SiN layer 106b peels off from the USG layer 106a (often in a substantially circular fashion) during an annealing process such as TV sintering.

As described above, according to the fabrication method of the image sensor in accordance with the present invention, a surface of a USG layer is treated with a plasma comprising oxygen (e.g., O₂) and a SiN layer is formed on the USG layer. Therefore, the peeling phenomenon in which the SiN layer peels off from the USG layer can be reduced, minimized or prevented because an adhesive strength between the USG layer and the SiN layer may be enhanced. Accordingly, the present invention is advantageous in that it can improve the productivity and yield of the image sensor.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A method of fabricating an image sensor, the method comprising the steps of:
patterning a metal pad on a circuit region of a substrate;
forming an Undoped Silicate Glass (USG) film on the substrate so as to cover the metal pad;
treating a surface of the USG film with a plasma comprising oxygen (O₂);
forming a silicon nitride (SiN) film on the plasma treated USG film;
selectively etching the SiN layer and the plasma treated USG layer to expose the metal pad; and
forming a color filter array and a microlens on the SiN film over a photosensitive element region of the substrate.

2. The method of claim 1, wherein the step of plasma treating the surface of the USG film includes employing a chemical dry etching process using a remote plasma apparatus.

3. The method of claim 2, wherein the chemical dry etching process comprises a flow rate of oxygen (O₂) gas within a range of from 400 to 500 sccm.

4. The method of claim 2, wherein the chemical dry etching process comprises a pressure of the plasma within a range of from 40 to 50 Pa.

5. The method of claim 2, wherein treating with the plasma comprising oxygen (O₂) is conducted for a length of time of from 50 to 100 sec.

6. The method of claim 1, further comprising the step of forming the metal pad on the circuit region of the substrate.

7. The method of claim 6, wherein the step of forming the metal pad comprises the step of:
sequentially forming a lower barrier film comprising a metal material, the metal pad and an upper barrier film on or over the substrate.

8. The method of claim 7, wherein the step of patterning the metal pad comprises the step of:
selectively stripping a portion of the lower barrier film, the metal pad and the upper barrier film.

9. The method of claim 8, further comprising forming an insulating film on the substrate, wherein the lower barrier film is formed on the insulating film.

10. The method of claim 1, wherein the step of forming the color filter array comprises the steps of:
forming a first planarization layer on the SiN film over the photosensitive element region of the substrate; and
forming the color filter array on the first planarization layer.

11. The method of claim 10, further comprising forming a second planarization layer to cover the color filter array.

12. The method of claim 11, wherein the step of forming the microlens comprises the step of:
forming the microlens on the second planarization layer.

13. The method of claim 1, wherein the step of plasma treating the surface of the USG film comprises chemical dry etching.

14. The method of claim 1, wherein the step of plasma treating the surface of the USG film employs a remote plasma apparatus.

15. The method of claim 3, wherein the chemical dry etching process comprises a pressure of the plasma within a range of from 40 to 50 Pa.

16. The method of claim 3, wherein treating with the plasma comprising oxygen (O₂) is conducted for a length of time of from 50 to 100 sec.

17. The method of claim 15, wherein treating with the plasma comprising oxygen (O₂) is conducted for a length of time of from 50 to 100 sec.
